(19) United States
(12) Patent Application Publication
(10) Pub. No.: US 2002/0154040 A1
(43) Pub. Date: Oct. 24, 2002

(54) Lossless data compression method enabling fast decompression

(76) Inventor: Pentti Vataja, Vantaa (FI)

Correspondence Address: PENTTI VATAJA, KEROKUJA 3 A 6, VANTAA, 01280, FI

(21) Appl. No.: 09/681,521

(22) Filed: Apr. 23, 2001

(51) Int. Cl. H03M 7/00

(52) U.S. Cl. 341/50

(57) ABSTRACT

A lossless data compression method that enables fast decompression is presented. To roughly characterize the method essential is that the finding of the repetitions is based on symbol pairs. The method repeatedly finds pairs formed by two adjacent symbols and replaces occurrences of common pairs with one new symbol. Similar prior art methods store the replacement rules into a separate entity that itself has to be compressed using some technique. The presented method does not need the replacement rules—the compressed symbol sequence is built in a new way, which enables that the replacement rules can be inferred from the symbol sequence. In prior art decompression, the replacement rules are decompressed and then consulted to interpret the symbol sequence and produce the original uncompressed input. The presented method enables decompression without recursion in one sequential traversal of the compressed input. To overcome the need to have a separate list of replacement rules the following method is used: The first one of the occurrences of a pair is not replaced. Later in the algorithm when no more symbols are replaced every introduced new symbol that still exists is turned to be a pointer to the corresponding first occurrence of the pair. A pointer is the position of the first symbol of a pair. To distinguish between atomic symbols i.e. symbols from original uncompressed input and pointers a constant value greater than any atomic value is added to a pointer value. The decompression traverses the compressed sequence and keeps track of each compressed position's decompressed length and starting position in the decompressed sequence. For every pointer position in compressed input, the number of decompressed symbols indicated by the pointed position and the next one are copied to decompressed output.

### BACKGROUND OF INVENTION

The purpose of data compression is to reduce the amount of storage space or communications bandwidth a particular piece of data requires. Several methods have been developed. In this method, we consider lossless compression where after the decompression the data appears exactly as it was before the compression and decompression. Following the common terminology we speak of symbols when in fact, they can be any characters, byte values, two byte values or new values introduced by the compression algorithm. Our method as many other methods rely on finding repetitions of symbol sequences. Compression is achieved by replacing equal symbol sequences with new and hopefully shorter symbols. The relationship between the new symbols and the symbol sequences they replace must also be somehow delivered to the decompressor. Well known is the Ziv and Lempel 77⁷ method. In that method, a symbol sequence is replaced by a pointer backwards to a previous occurrence of the same sequence and the length of this occurrence. Our method of finding the repetitions differs from that of Ziv and Lempel 77. However, we also use a pointer backwards but we don't have to tell the length of the pointed sequence.

After our method is applied, the resulting symbol sequence can be e.g. Huffman coded or arithmetic coded. For an overview of compression techniques see Witten, I. H., Moffat, A., and Bell, T. C., 1999. Managing Gigabytes: compressing and indexing documents and images⁶.

To find the repetitions we use a modified earlier presented algorithm. To roughly characterize the method essential is that the finding of the repetitions is based on symbol pairs. The technique repeatedly finds pairs formed by two adjacent symbols and replaces occurrences of common pairs with one new symbol. Some studies have been performed concerning this technique. Common to them is that the result will consist of two entities: replacement rules and a symbol sequence. During the decompression, the replacement rules are consulted to interpret the symbol sequence and produce the original uncompressed input. The presented invention does not need the replacement rules—the symbol sequence is built in a new way, which enables that the replacement rules can be inferred from the symbol sequence.

Rubin⁵ gives an early version of the repetition finding algorithm. Later this algorithm is presented by Larsson² and by Larsson and Moffat³. Similar technique is also presented by Cannane and Williams¹. They also store and compress the replacement rules—which they call phrase dictionary—as separate entity. Slightly different is a grammar-based approach called the SEQUITUR⁴. However, it is also symbol-pair based and collects the replaced symbol-pairs into grammar rules. Again, the phrases i.e. the rules of the grammar are separately compressed.

1. Cannane, A., Williams, H. E., General Purpose Compression for Efficient Retrieval. Journal of the American Society for Information Science and technology vol 52(5), 430-437, 2001.

2. Larsson, N. J., 1999. Structures of string matching and data compression, p. 91-110. Doctoral dissertation. Department of Computer Science, Lund University, Sweden.

3. Larsson, N. J., Moffat A., Offline dictionary-based compression. IEEE Data Compression Conference, 1999, Snowbird, Utah, p. 296-305. IEEE Computer Society Press, Los Alamitos, Calif.

4. Nevill-Manning, C. G., Witten, I. H., D. R. Olsen, Jr., Compressing semi-structured text using hierarchical phrase identification. IEEE Data Compression Conference, 1996, Snowbird, Utah, p. 63-72. . IEEE Computer Society Press, Los Alamitos, Calif.

5. Rubin, F., Experiments in text compression. Communications of the ACM 19(1976), no 11, 617-623.

6. Witten, I. H., Moffat, A., Bell, T. C., 1999. Managing Gigabytes: compressing and indexing documents and images. Second edition. Morgan Kaufmann publishers.

7. Ziv, J., Lempel A., 1977. A universal algorithm for sequential data compression. IEEE Transactions on Information Theory IT-23(3):337-343, May.

### SUMMARY OF INVENTION

In a prior art algorithm, a main loop finds the most frequently existing pair of two adjacent symbols (e.g. bc). All occurrences of these two symbols are studied and replaced by a new symbol (e.g. E). This replacement rule (bc>E) is recorded in a separate list which itself has later to be compressed. This finding and replacing loop continues until no two adjacent symbols occur more than a predetermined times. The algorithm uses a symbol sequence array, a hash table and a priority queue as data structures. Whenever a replacement is done, the data structures are updated to reflect the new symbol sequence after the replacement and the new frequencies (e.g. abcd becomes aEd and the frequencies of ab and cd are lessened by 1 and the frequencies of aE and Ed are increased by 1). The decompression needs the list of replacement rules and the symbol sequence.

On our method, we do not need a separate list of replacement rules. This information can be delivered in the compressed sequence itself. We also introduce methods to speed up the updating of each pair's properties. This in prior art requires a hash table lookup. The purpose is to lessen the amount of hash table lookups and priority queue updates. The updating of the priority queue can be postponed to a moment when all the occurrences of a pair have been studied. Also new arrays can be introduced to lessen the amount of hash table lookups. Using these arrays only 1 hashing per pair is required when a pair's position in the priority queue is reconsidered.

To overcome need to have a separate list of replacement rules the following method is used: The first one of the occurrences of a pair is not replaced. Later in the algorithm when no more symbols are replaced every introduced new symbol that still exists is turned to be a pointer to the corresponding first occurrence of the pair. A pointer is the position of the first symbol of a pair. Each pointer now represents two other symbols: either of them can be an atomic symbol or a pointer. To distinguish between atomic symbols and pointers a constant value greater than any atomic value is added to a pointer value. This approach of using the first pair as an explanation of symbols meaning or as a replacement rule also makes the decompression very simple. The decompression traverses the compressed sequence and keeps track of each compressed position's decompressed length and starting position in the decompressed sequence. For every position in compressed input, the number of decompressed symbols indicated by the position's then known length is copied to decompressed output. An atomic symbol's length is 1 and a pointer's length is the combined length of the two other positions it points to. No recursion is needed in decompression. The presented method of leaving one pair and transforming the corresponding symbol to a pointer needs a careful counting of the adjacent symbols' frequencies and an extra bit per symbol is required during the computation to tell that a symbol cannot be replaced. For each pair of symbols the prior art algorithm keeps track of each pair's occurrence number, the current invention counts the number of those occurrences that can be replaced.

Other strategies of choosing the occurrence of a pair that is not replaced are discussed briefly. Comparing to other strategies the presented one of choosing the first occurrence enables a very fast and straightforward decompression.

The speed up methods are discussed next. A pair's properties are stored in a record that is in a double linked priority queue list. The number of replaceable occurrences of a pair determines the list in question. If the priority queue update is done immediately after each number change, these double linked lists have many changes. The priority queue update can be postponed to the point of next needed finding of a pair of greatest number of replaceable occurrences. One array is used to store the indexes of changed records (or pointers to those records). When the priority queue update must be done, the array is traversed and the records moved, each only once.

Another speed-up method with fewer hash table lookups is also presented. Consider the phase where all occurrences of a chosen pair are studied for a possible replacement by a new symbol. Thus e.g. abcd will become aEd when E is a new symbol replacing the pair bc. Now we introduce an array indexed by the symbols appearing at left side of pair bc, in this case “a” to store a record that will store the number of replaceable occurrences change for pairs ab and aE and other needed information. Similarly we have an array for the symbols that will appear at right side of bc, in this case it is indexed by “d”. Now for most cases the number of replaceable occurrences changes in synchrony—e.g. the pair ab will lose 1 occurrence and pair aE will gain 1 occurrence. There are cases when the number to be decremented will differ from the number to be incremented. They can be found and 5 variables are required to store the needed information. When all the occurrences of the pair bc have been studied, the two arrays and the 5 variables are studied and each new pair is only once hashed and inserted into the hash table list and into the priority queue. Then also the priority queue move for previously existing pairs is done.

### BRIEF DESCRIPTION OF DRAWINGS

Referring to FIG. 1a. The symbol sequence is stored in an array whose records have the following 3 fields:

Pointer to previous occurrence of this pair

Symbol's value

Pointer to next occurrence of this pair

Symbol's value can have a negative sign indicating that this position cannot be replaced. The pointers are the positions of the previous and next occurrence of the pair that this symbol and the next one form.

FIG. 1b gives an example of a symbol sequence and the corresponding symbol sequence array.

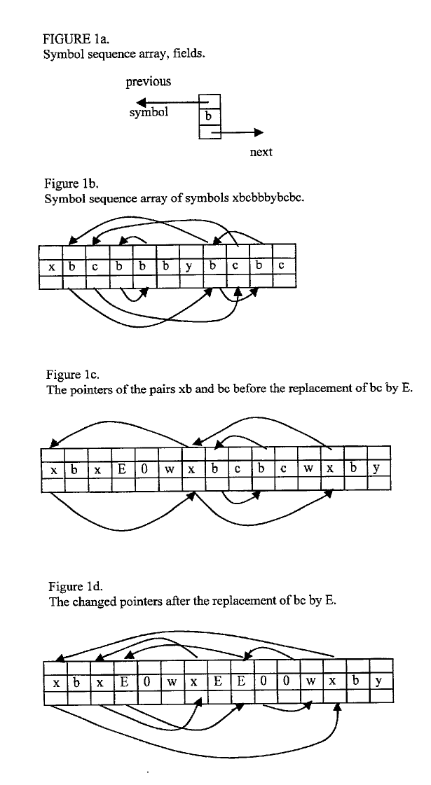

FIG. 1c gives a symbols sequence array before the replacement and the FIG. 1d after the replacement.

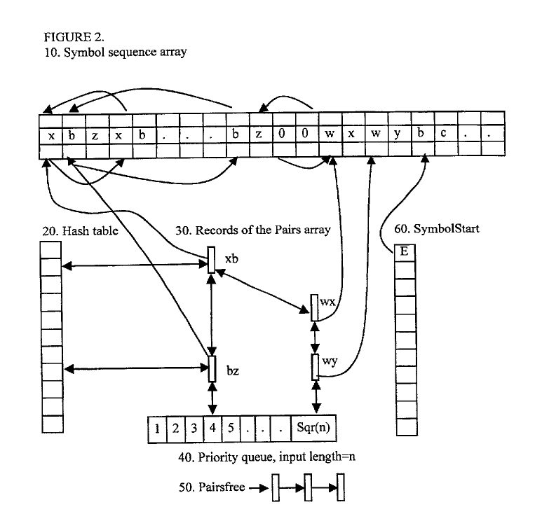

FIG. 2 shows the symbol sequence array 10. An array hash table 20 is used to locate the records 30 storing the properties of a pair. Hash table has 1 field:

Index of a record in Pairs array

This value is set to −1 if no record has been hashed to the index value of this slot. Those pair values that hash to same slot are in a double linked list. An array priority queue 40 to find the greatest number of replaceable occurrences. It has 1 field:

Index of a record in a Pairs array

Priority queue is indexed from 0 to SqrLenInp. SqrLenlnp is the square root of the input length. This is calculated when the symbol sequence array is build. Entries in the priority queue point to records in the Pairs array. These records have a double linked priority queue list. Those pair records having the number of replaceable occurrences greater or equal to SqrLenInp are in the same priority queue list, other values have each a list of their own.

An array Pairs stores the records 30 that the hash table and the priority queue point to. Each record has the following 9 fields:

First symbol value

Second symbol value

First position

Last seen previous position

Number of occurrences that can be replaced

Previous in hash table list

Next in hash table list

Previous in priority queue list

Next in priority queue list

The re-usable records of the Pairs array are collected into a list pointed by a Pairsfree variable 50. This list uses the field “Next in hash table list” in Pairs array records 30.

A SymbolStart array 60 to store the position of the first occurrence of a pair a new nonatomic symbol replaces. An index into this array is the value of the new nonatomic symbol. Value returned is the position: SymbolStart (symbol E)=position of the first symbol from pair bc when symbol E replaced the pairs bc in the symbol sequence array.

FIG. 3 shows the fields of a record in the arrays LeftChanges and RightChanges used in algorithm A3 to store a changed pair's properties. They have the following 3 fields:

First position

Last seen previous position

Number of changes

### DETAILED DESCRIPTION

Algorithm A1.

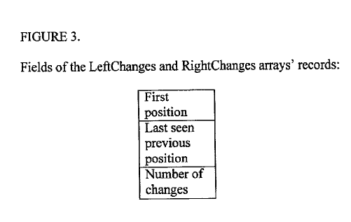

To give overview we give first a sketchy description of the compression algorithm. Later, a detailed description is shown. The data structures are in FIG. 2. Input consists of symbols, usually but not necessarily between 0 and 255. All input symbols are below upperlimit.

Step 1. The input symbols are traversed from left to right once. A pair is two adjacent symbols. The number how many times each pair exists is counted and stored in a record 30 as a number of replaceable occurrences. One record of storage is used for each pair. The input symbols are inserted into symbol sequence array 10.

Step 2. These records containing each pair's number of replaceable occurrences are inserted into priority queue 40 lists. The number determines the priority queue list in question.

Step 3.

(a) Find from the priority queue the pair having the greatest number of replaceable occurrences.

(b) The two symbol positions in the symbol sequence array 10 of the first occurrence of the pair found in step 3a are marked not replaceable. If this marking decrements the number of replaceable occurrences for pairs formed by symbols adjacent to chosen pair's symbols then the affected pairs' records are moved into proper positions in the priority queue lists.

(c) Introduce a new symbol, not existing before. The position of the first symbol of the first occurrence of the pair chosen in step 3a is stored into an array SymbolStart 60 indexed by the corresponding new symbol's value.

(d) The other occurrences of this pair are studied and those occurrences whose both symbols are replaceable are replaced with the new symbol. If this marking decrements or increments the number of replaceable occurrences for pairs formed by symbols adjacent to an occurrences symbols then the affected pairs' records are moved into proper positions in the priority queue lists.

This step 3 continues from the beginning of it until the greatest number of replaceable occurrences found descents to a given limit.

Step 4. If the given limit of greatest number of replaceable occurrences is 1 then this step 4 is done. The symbols are traversed form left to right and if there is a pair whose second occurrence's both symbols are replaceable then the second occurrence is replaced by a new symbol. The position of the first symbol of the first occurrence is stored into a SymbolStart 60 array indexed by the corresponding new symbol's value. During one traversal of the symbols, all such replaceable pairs have been found.

Step 5. The symbols are traversed from left to right once and moved to the output array. Every symbol that was used to replace an occurrence of a pair is transformed to a value that is the position of the first symbol of the first occurrence of the replaced pair plus a constant value upperlimit, which is greater than any symbol in input. The position of the first occurrence's first symbol in symbol sequence array is obtained from the SymbolStart array 60 indexed by the symbol's value. The position in symbol sequence array is transformed to be a position in the output array. This step 5 is done in one traversal of the symbols.

The decompression is described next. Recall that the compressed sequence consists of atomic symbols i.e. some symbols from original uncompressed input and pointers. A pointer is a value of the position pointed to plus a value called upperlimit that is greater than any atomic symbol's value.

Step 6. The algorithm can now finish.

For each position X in compressed input:

Step 1. Determine if a position X in compressed input contains an atomic symbol or a pointer: if the value is less than upperlimit then the position contains an atomic symbol.

Step 2. If a position X contains an atomic symbol then copy the atomic symbol to the next unoccupied position Z in decompressed output and set

Length₁₃ of₁₃ position (X)=1

Starting₁₃ position(X)=Z

else if a position X contains a pointer to a position Y then set

E=Length₁₃ of₁₃ position(Y)+Length₁₃ of₁₃ position(Y+1)

and copy E positions to next unoccupied position Z in decompressed output from decompressed output from the position Starting₁₃ position(Y) and set

Length₁₃ of₁₃ position(X)=E

Starting₁₃ position(X)=Z.

The decompression is done in one traversal of the compressed input.

Comparing the current invention to prior art new is the idea of leaving the first occurrence of a pair in the compressed sequence and transforming as last step of the compression the replaced occurrences to pointers to this first occurrence. This eliminates the need to apply compression techniques to the separate list of replacement rules. In addition, the decompression is very straightforward requiring only one traversal of the compressed sequence. In prior art decompression, this list must first be decompressed and then the list must be consulted during the decompression of the compressed symbol sequence. The already mentioned fundamental difference also leads to other differences in the algorithms. For example, the prior art algorithm thus does not have to separate symbol positions into replaceable and not replaceable. The prior art method counts all of pair's occurrences whereas the current invention counts only replaceable occurrences. The prior art algorithm and the presented one have same kind of data structures: hash table, priority queue, and symbol sequence array. Their exact usage varies depending on the differences in the algorithms and in the coding style.

Now the detailed description is shown. The data structures are in FIG. 2. First, some often-used routines of the algorithm are described.

The procedure PutIntoPairs is called when a pair is inserted into the hash table linked list. The pair may also already be there. Parameters are the position of the first symbol of the pair in the symbol sequence array 10, the first and the second symbol of the pair and a number indicating the increment of the pair's number of replaceable occurrences. The method returns the pair's index in the Pairs array 30 as last parameter. First PutIntoPairs checks if the hash table linked list is empty. If not then the list is traversed in order to find a record whose symbols match those of the input parameters. If this record 30 is found then the number of replaceable occurrences is incremented by the value of the input parameter. In addition, the pointers in the symbol sequence array 10 are updated for this new occurrence of this pair. This means that the position found in the record's “Last seen previous position” field is set to point to the position of the first input parameter. The symbol sequence array's 10 previous pointer at the position of the first input parameter is set to have this “Last seen previous position” value. The field “Last seen previous position” of the record 30 is then set to the value of the first input parameter. The symbol sequence array's 10 next pointer is set to nil (-1) value. This was the case when the record already was in the Pairs array 30. Now if the record was not found then first it is checked if the re-usable list 50 is not empty. If it is not empty then the first one of its records is used to store this pair's properties. If the re-usable list 50 is empty then a new record is allocated from the Pairs array 30. The record is put into the first position of the double linked hash table list. The field “Last seen previous position” and the field “First position” of the record 30 is then set to the value of the first input parameter. The symbol sequence array's 10 next and previous pointers are set to nil (−1) value.

Next, we describe the method to skip the positions that become empty because of a replacement. Let abcbcbcd be a symbol sequence in the symbol sequence array 10 from which bc will be replaced by E. The compression algorithm will find that there are 3 consecutive occurrences of bc. The symbol E is put to 3 consecutive positions starting from and including the first b. The position immediately following the last E will be set to 0. Another 0 is set to the last position of the replaced symbol sequence. Thus, the new sequence will be aEEE0 b0 d. The pointers of the symbol sequence array at the 0 valued positions are set to point to one pass each other, skipping the other 0 and the b symbol between them. Thus the first 0's next pointer will point to position of the second 0 plus 1 and the second 0's previous pointer will be set to point to the first 0's position minus 1. Whenever in the computation the symbol following for e.g. the last E is needed it is known that if the symbol at the next position is 0 the needed symbol is at the destination of the next pointer of the found 0 position.

A procedure called FixPointers is used to set the symbol sequence array's 10 pointers for disappearing pairs. Let again abcbcbcd be a sequence from which bc will be replaced by E forming the sequence aEEEd (shown without the empty positions). The parameters of FixPointers are the edge positions “a” and “d” and the position of the first symbol of the pair whose pointer need to be set and the absolute symbol values of the pair whose pointers need to be set. An absolute (abs) value is the value without the sign, abs(−1)=1. Note that in the example 1 occurrence of pairs ab and cd and 2 occurrences of pair cb will disappear. Let positions of “a” and “d” and the position posf and the absolute symbol values m and n be the parameters of Fixpointers. Now set p to be the value of posf s previous pointer and r the value of its next pointer. Now move p to the left using previous pointers until p is less than position of “a”. Move r to the right using the next pointers r until r is greater or equal to position of “d”. If this p is not a null pointer (we use −1) then there is a previous occurrence of mn and so set the next pointer at position p to point to r. Similarly if there is an r position set its previous pointer to p. If there was no previous occurrence of mn then this one is the first one and since it now disappears the field “First position” in the Pairs array record 30 must now be updated to point to r. The record in the Pairs array is found using the hash table 10. In our example the Fixpointers would be called three times, always with edge positions “a” and “d” but with first positions and symbol values corresponding to ab, cd and cb.

CountSimil counts the number of consecutive occurrences of a given symbol up to the first different symbol or not replaceable symbol position. If a disappearing pair's symbols are equal then CountSimil is used to determine if the number of replaceable occurrences of this disappearing pair is to be decremented. This function's parameters are the direction (left or right), and the position from which to start the counting. As an example, we use a sequence bbbbbcy that has 5b symbols but 2 occurrences of the pair bb. When the pair bc is replaced by E then in the new sequence bbbbEy there is still 2 occurrences of the pair bb left. The sequence bbbbcy has 4 b symbols and after the replacement, the bbbEy has only 1 occurrence of bb left. Thus, CountSimil is needed to count the number of “b” symbols.

Next the priority queue's 40 lower and upper bounds are described. The priority queue is indexed from 0 to SqrLenInp, where SqrLenlnp is the square root of the input length. This is calculated when the symbol sequence array is build.

This upper bound is suggested by Larsson². Using this bound the following nice theoretical result can be shown: the total time the algorithm needs in finding the pair having the greatest occurrence number is O(n), where n is the number of input symbols. This result also applies to the current invention. Those pairs having the number greater than or equal to SqrLenlnp are in th last list. Others are in a list for each number below SqrLenlnp.

The Decrement procedure is used to update the priority queue 40 and the priority queue pointers in Pairs array records 30 as well as the number of replaceable occurrences itself. Let's use the same example as in previous chapter, abcbcbcd. The first parameter is the decremented number—let it be k. The second and third parameters are the symbols of the pair. Now use hash table 20 to find this pair's record 30. Decrement the number of replaceable occurrences by k. If the result is greater than or equal to SqrLenInp, then nothing needs to be done and the procedure can quit. (The record is in the last priority queue list and still belongs there). Otherwise, disconnect the record from its previous and next record in the double linked priority queue list. Connect these records to each other. If the new number of replaceable occurrences is greater than Numlimit then put this record into the first position in the priority queue indexed by the new number. If the new number is less or equal to Numlimit then this pair is moved to a list of reusable records 50. First, disconnect this record from its double linked hash table 10 list and connect its previous and next hash table list records to each other. Then set this record's “Next in hash table list” pointer to point to the record pointed by Pairsfee variable. Then set the Pairsfree to point to this record.

The procedure Increment moves the Pairs array record 30 from one priority queue 40 list to another list. The first parameter is the index of thep record in question, second parameter is the value of the increment. This procedure is called for such symbol pairs whose number of replaceable occurrences is increasing and for this reason records are put into a new list even if this number is below-or equal to Numlimit.

Now the algorithm is given.

The input is a sequence of atomic symbols x, 0<=x<upperlimit (typically 1 byte long: 0<=x<256). Nonatomic symbols are new symbols that start from upperlimit and each new nonatomic symbol is the previous one +1.

Step 1. Reading of an input into symbol sequence array 10. Referring to FIG. 2. Input array is scanned from left to right once. Insert every symbol into symbol sequence array 10 and add 1 to each symbols value. The procedure PutIntoPairs is used to update the Pairs array records 30 for each pair formed by two consecutive symbols. If there are RLcount consecutive occurrences of a same symbol then the number of replaceable occurrences of the pair in question is incremented by RLcount\2(4\2=2,5\2=2). E.g. in a sequence bbba there is one occurrence of the pair bb. The following code does this reading.

Variable Explanation

A original input is in this array

si Index in symbol sequence array

prev Previous symbol value

RLcount Number of consecutive occurrences of a pair

oldnum previous number of occurrences

IndexInPairs index in Pairs array 30

A notation X(i).z means that a record's field z is referenced at index position i of array X.

For i=1 To the end of input array A

Si=Si+1

symbol₁₃ sequence₁₃ array(si).symbol=A(i)+1

If A(i) +1=prev Then

RLcount=RLcount+1

PutintoPairs ai−1, prev, prev, 1, IndexInPairs

If RLcount=2 Then

oldnum=Pairs(indexinPairs).number−1

End If

Else

If RLcount>1 Then

Pairs(IndexinPairs).number=oldnum+RLcount 2

End If

RLcount=1

PutIntoPairs ai−1, A(i−1)+1, A(i)+1, 1, IndexinPairs

prev=A(i)+1

End If

Next I

If RLcount >1 Then

Pairs(lndexinPairs).number =oldnum +RLcount 2

End If

Step 2. Initial inserting of the records of Pairs array 30 into the priority queue 40 lists. Referring to FIG. 2. Recall that the priority queue is an array whose values are indexes in the Pairs array. The priority queue is indexed by a number and this is the number of replaceable occurrences of all the records in the same double linked list starting from the first record. The last priority queue entry is an exception: in this list there are numbers greater than or equal to the square root of input length. Let Numlimit be a number and let SqrLenlnp be the square root of input length. Go through the pair records in Pairs array 30. Insert every record having the number of replaceable occurrences greater than or equal to SqrLenlnp into the last priority queue list. Every record having a number greater than Numlimit and less than SqrLenInp is inserted into the list pointed by its number. If the number is less than or equal to Numlimit then disconnect the record from its double linked hash table list and connect the previous record and the next record to each other. Next, it is moved to a list of re-usable records 50. Set this record's “Next in hash table list” pointer to point to the record pointed by Pairsfee variable. Then set the Pairsfree to point to this record.

Step 3. Looping until the greatest number of replaceable occurrences is Numlimit. Referring to FIG. 2. This is the main loop of the algorithm. When this loop finishes all priority queue lists above Numlimit are empty.

(a) Find from the priority queue 40 the pair having the greatest number of replaceable occurrences. This is achieved by going through the list pointed by the last priority queue entry, SqrLenlnp, if it is not empty. If this list is empty then take the first record 30 in the first nonempty list found going down from SqrLenlnp. Note that a newly found greatest number of replaceable occurrences cannot exceed any previously found and thus the priority queue's 40 starting positions are studied in descending order. Use this found record's field “First position” to find the starting position in symbol sequence array 10.

(b) Let b be the symbol in this first position. Let c be the symbol in next position (empty positions skipped). Let the symbol before b be “a” and the symbol after “c” be “d” thus forming a sequence abcd.

The left side.

If a>0 then

If abs(a)=abs(b) then

If abs(b)<>abs(c) then

If CountSimil(Left,Position of a) mod 2=0 then

Decrement 1,abs(a),abs(b)

End if

End if

Else

Decrement 1,abs(a),abs(b)

End if

End if

The right side.

If d>0 Then

If abs(c)=abs(d) Then

If abs(b)<>abs(c) Then

If CountSimil(Right, Position of d) Mod 2 =0 Then

Decrement 1, abs(c), abs(d)

End If

End If

Else

Decrement 1, abs(c), abs(d)

End If

End If

Next, set the symbols b and c values negative indicating they are part of a first occurrence of a replaced pair. Index the SymbolStart array by abs(b) and set this Symbolstart(abs(b)) to have a value of the position of b.

(c) Using the next pointer of this first position in the symbol sequence array 10 study all the other occurrences of this pair bc.

If one of the symbols in an occurrence is negative then the occurrence's first symbol's previous and next pointers to null (−1).

If in an occurrence both the first and second symbols are positive then find the number of consecutive occurrences of this pair requiring all symbols of these occurrences being positive. Let RLcount be this number (we use now abcbcbcd as an example, RLcount is thus 3). First, the left pair ab is dealt with. Using the following logic apply the procedures Decrement and FixPointers, when bc is the pair to be replaced and “a” the symbol before the first pair. The following logic sets the pointers of disappearing occurrences ab, cb and cd. The procedure Decrement is called for special cases when a=b or a=c.

wasmiddle=False

sgnA=symbol “a” with the sign i.e. sgnA can be also negative

If abs(b)<>abs(c) Then

FixPointers position of “a”, position of “d”, position of “a”, abs(a), abs(b)

If sgnA=abs(b) Then

If CountSimil(Left, position of “a”) Mod 2=0 Then

Decrement 1, abs(a), abs(b)

End If

Elself sgnA =abs(c) Then

Decrement 1, abs(a), abs(b)

wasmiddle=True

End If

Elself abs(x) <>abs(b) Then

FixPointers position of “a”, position of “d”, position of “a”, abs(a), abs(b)

End If

Next the right pair cd is dealt with. The pair to be replaced is bc and “d” the symbol after the last pair. The variable wasmiddle is used ensure that the pair cb's pointers are set only once. The procedure Decrement is called for special cases when c=d or b=d:

sgnD=symbol “d” with the sign i.e. sgnD can be also negative

If abs(b)<>abs(c) Then

abs(c) =abs(d) Then

FixPointers position of “a”, position of “d”, position of the last “c”, abs(c), abs (d)

If sgnD >0 Then

If CountSimil (Right, position of “d”) Mod 2 =0 Then

Decrement 1, abs(c), abs(d)

End If

End If

Elself abs(d) =abs(b) Then

If Not wasmiddle Then

FixPointers position of “a”, position of “d”, position of the last “c”, abs(c), abs(d)

wasmiddle=True

End If

If sgnD >0 Then

Decrement 1, abs(c), abs(d)

End If

Else

FixPointers position of “a”, position of “d”, position of the last “c”, abs(c), abs (d)

End If

Elself abs(c) <>abs(d) Then

FixPointers position of “a”, position of “d”, position of the last “c”, abs(c), abs (d)

End If

Next, the middle pair cb. In a sequence abcbcbcd where RLcount is 3(3 occurrences of bc) there are 2 occurrences of cb. Again wasmiddle is used to ensure that the pointers of the middle pair are set only once.

If abs(b)<>abs(c) And RLcount>1 Then

If Not wasmiddle Then

FixPointers position of “a”, position of “d”, position of last “c”, abs(c), abs(b)

End If

Decrement RLcount−1, abs(c), abs(b)

End If

In previous calls for the Decrement procedure, only some special cases were dealt with. Now the other cases for decrementing the number of replaceable occurrences are considered. In addition, the new pairs aE and Ed are inserted into the hash table 20 double linked list and into the priority queue 40 lists. The IndexInpairs variable is returned by the PutIntoPairs. It tells the pair's record's index in the Pairs array 30:

The left side and the pair aE.

If sgnA>0 Then

If abs(a)<>abs(b) And abs(a)<>abs(c) Then

Decrement 1, abs(a), abs(b)

End If

PutintoPairs position of “a”, abs(a), E, 0, IndexinPairs

Increment IndexInPairs ,1

Else

PutintoPairs position of “a”, abs(a), E, 0, IndexInPairs

End If

The right side and the pair Ed.

If d >0 Then

If abs(d)<>abs(b) And abs(d)<>abs(c) Then

Decrement 1, abs(c), abs(d)

End If

PutIntoPairs position of first b +RLcount - 1, E, abs(d),0, IndexinPairs

Increment IndexInPairs, 1

Else

PutIntoPairs position of first b +RLcount - 1, E, abs(d),0, IndexInPairs

End If

Next put the new symbol (let it now be E) RLcount times into positions starting from and including the now replaced sequence's first symbol:

For i=position of first “b” To position of first “b” +RLcount −1

symbol-sequence-array(i).symbol=E

Next i

There will be RLcount2 new occurrences of the pair EE. Also, update the priority queue 40:

If RLcount>1 Then

For i=position of first “b” To position of first “b” +RLcount−2

PutIntoPairs i, E, E, 0, IndexinPairs

Next i

Increment IndexinPairs, RLcount 2

End If

To skip the empty positions set the next pointer of the first and the previous pointer of the last of those positions that became empty because of replacement by 0:

s1 =position of first “b” +RLcount

s2 =position of “d” - 1

symbol₁₃ sequence₁₃ array(s1).symbol =0

symbol₁₃ sequence₁₃ array (s2) symbol =0

symbol₁₃ sequence₁₃ array (s1 ).next=position of “d”

symbol₁₃ sequence₁₃ array (s2).previous=s1 - 1

This step 3(c) continues until all the occurrences of the pair have been studied.

(d) When all the occurrences of a pair have been studied for possible replacement, the first occurrence's first symbol's next pointer in the symbol sequence array 10 is set to null (−1). In addition, this pair's record is disconnected from its priority queue and hash table list, the record's previous and next records in the corresponding lists are connected to each other. Then the record is moved to the re-usable list 50 by setting the record's “Next in hash table list” pointer to point to the record pointed by Pairsfee variable and setting the Pairsfree to point to this record. Next, the priority queue 40 lists up to and including Numlimit are traversed and those records are put into the re-usable list 50. The computation of this step 3 “Looping until the greatest number of replaceable occurrences is Numlimit” will continue from the start of it.

Step 4. This step is done if the Numlimit value is 1. This means that all those pairs that have at least 2 occurrences whose all symbols are positive have been processed. There may still be some pairs whose first pair has one or two negative symbols but the second occurrence has two positive symbols. The second occurrence of that pair could thus be replaced by a new nonatomic symbol. Now this step goes through the symbol sequence array and if a position has a next pointer then it is checked if the occurrence pointed to has two positive symbols of the pair. If this is the case then the first symbol of the second occurrence is set to have the value of the new nonatomic symbol and the second symbol is set to 0. The array SymbolStart indexed by the new symbol is set to have the value of the position of the first symbol of the first occurrence. The next pointer of the 0's position is set to point to the next symbol. During one traversal of the symbol sequence array's symbols, all such replaceable pairs have been found.

Step 5. Now the array Symbolstart contains the positions of the first symbols that each nonatomic symbol was used to replace. The array Result is used to hold the final output of the algorithm. A temporary array TA is used also. Now go through the symbols of the symbol sequence array 10. It contains some of the original atomic values and the new nonatomic symbols. Use the SymbolStart array to replace each occurrence of a symbol by its starting position in the Result array plus a constant value upperlimit. Use temporary array TA to transform the position in the symbol sequence array to position in the Result array. Remember to decrement the value of atomic symbols by 1, which was added at the step 1. More formally:

r=−1

For each symbol position i do

if symbol at symbol sequence array's position i is'nonatomic Then

r=r+1

TA(i) =r

Result(r) =TA(SymbolStart(symbol)) +upperlimit

else

r=r+1

TA(i) =r

Result(r) =symbol - 1

End If

Next i

Step 6. Now the algorithm can finish. The output, the array Result can be e.g. Huffman coded or arithmetic coded.

For example, the algorithm Al compresses when Numlimit is set to 1 the first 1.000.000 bytes of the bible.txt in the Canterbury corpus into 125.699 positions. A canonical Huffman compression of the compressed sequence will then produce a result of 220.492 bytes. This means 1.76 bits/byte.

Next, we discuss briefly whether it would be better to choose the pair to be left as an explanation of a replacement rule in a different way. E.g., let . . . bcabcd . . . be a sequence where ab and cd are already chosen not to be replaced. If the first bc is chosen to be left in the compressed sequence then the second occurrence of the pair bc cannot be replaced since both of its symbols are marked not replaceable. However, if the second occurrence of bc is chosen then the first bc can be replaced. The author tested a method that found a pair whose one symbol was already marked to be not replaceable and left this pair in the compressed sequence. In the tests the compression result was not as good as in the method presented above—however, the difference was a very small one. In addition, the decompression is more complicated. When always the first occurrence of a pair is chosen then those first occurrences will also appear near each other. These consecutive occurrences of first pairs have common symbols and thus they use less space.

Algorithm A2. A speed up improvement.

In Algorithm Al the priority queue update is done immediately after pair's number of replaceable occurrences changes. This causes the double linked lists to have many updates. The priority queue update can be postponed to the point when all the occurrences of a chosen pair have been studied. When a pair's number of replaceable occurrences is changed, the index of this pairs record in the Pairs array 30 is inserted into an array called ChangedInds if it is not already there. To check that an index is not already in ChangedInds another array called ChangedCheck is used. This ChangedCheck is indexed by the Pairs array 30 index and has a value of 0 if the index is not in the ChangedInds array. If a Pairs array record's number of replaceable occurrences is decremented then its index is inserted into ChangedInd array with minus(−) sign, if the number is incremented the index is inserted with positive(+) sign. When all the occurrences of a pair have been studied for possible replacement, the indexes in the ChangedInds array show which Pairs array records must be repositioned regarding to priority queue lists. If an index has a negative sign then it is known that the record need not be repositioned if the number of replaceable occurrences is greater than or equal to SqrLenlnp. (The record is still in the last priority queue 40 list). If an index has positive sign and a number greater than or equal to SqrLenInp the record is inserted into the last priority queue list, in first position. If a record has a number less than or equal to Numlimit it is moved to the list of re-usable records 50, the sign of the index has no meaning in this case. If a record has a number greater than Numlimit and less than SqrLenlnp then it is inserted into the priority queue list indexed by the number of replaceable occurrences, in first position. To modify Algorithm Al according to the needs of the Algorithm A2 the procedures Decrement and Increment are modified to use arrays ChangedChecks and ChangedInds as described above. In addition, the array ChangedInds is traversed when all occurrences of a pair have been studied for possible replacement and the records are moved into proper positions as described above. In Algorithm Al when all occurrences of a pair have been studied for possible replacement the priority queue 40 lists up to and including Numlimit are traversed and those records are put into the re-usable list 50. In Algorithm A2 this is not done since records are moved into the re-usable list 50when the ChangedInds array is traversed.

This algorithm uses slightly more memory than algorithm A1 due to extra arrays.

Algorithm A3. Another speed up improvement.

Further improvements to the speed of Algorithm A1 can be done. This is a different one than the one presented in Algorithm A2. In practical tests, this has been the fastest one, it uses more memory than both previous ones. We give first the idea and show the exact description later. Let bc be a pair that is chosen to be replaced in a sequence . . . abcd . . . resulting to a sequence . . . aEd . . . If we consider the new pair aE then if aE's number of replaceable occurrences is increased then the number of replaceable occurrences of ab is decreased. An exception is the case when a=b. In the case when a=b thus the sequence being . . . bbcd . . . resulting to . . . bEd . . . the number of replaceable occurrences of bE will increase but the number of bb will decrease only if there are an even number of “b”-symbols. Similar rule applies to the right side: if d=c then Ec will increase but cc will decrement only if there are an even number of “c”-symbols. In other than those special cases the number to be incremented for the pair aE (Ed for the right side) is the same as the number to be decremented for pair ab (cd). Thus, all the number of replaceable occurrences changes for those pairs can be collected into two arrays, one for the left and one for the right side. In this case those arrays are indexed by “a” for left side and by “d” for right side. When a number of replaceable occurrences change happens the array value is incremented by 1. In addition, those arrays can be used to store the information for the new pairs aE and Ed that in Algorithm 1 is accessed via hash table 20 and stored in Pairs array records 30. This information is in two fields: “First position” and the “Last seen previous position”. When all the occurrences for a pair bc have been studied then those arrays are used to decrement the number of replaceable occurrences for pairs ab and cd in Pairs array records 30 and increment the numbers for pairs aE and Ed. Each pair thus requires 1 usage of the hash table. The above-mentioned field “First position” is also copied to Pairs array field for pairs aE and Ed. The other field “Last seen previous position” is only needed when all the occurrences for the pair bc are studied.

Three not yet mentioned special cases still exist. One is the pair cb in sequence abcbcd when bc is replaced. Second is the pair ab in sequence abcd when bc is the first occurrence of the pair bc. In this case, there is no replacement and there will be no new pair aE. In similar way the pair cd will be decremented but there will be no new pair Ed.

One variable for every special case is used. Three are used to store the number of replaceable occurrences change for the cases when the decremented number differs from the incremented number. Two are used to store the symbols adjacent to first occurrence. Thus, 5 variables are needed.

We now give the exact description of the Algorithm A3. Referring to FIG. 2.

The Step 1 “Reading of an input into symbol sequence array 10” and the Step 2 “Initial inserting of the records of Pairs array 30 into the priority queue 40 lists” are as in Algorithm A1.

A technical detail is that now the Pairs array record does not necessarily need the “Last seen previous position” field. In the step 1 the “Reading of an input into symbol sequence array 10” it can be replaced by a temporary array which is no more needed after the step 1.

Step 3. Looping until the greatest number of replaceable occurrences is Numlimit. This is the main loop of the algorithm. When this loop finishes all priority queue lists above Numlimit are empty.

(a) Find from the priority queue 40 the pair having the greatest number of replaceable occurrences. This is achieved by going through the list pointed by the last priority queue entry, SqrLenlnp, if it is not empty. If this list is empty then take the first record 30 in the first nonempty list found going down from SqrLenlnp. Note that a newly found greatest number of replaceable occurrences cannot exceed any previously found and thus the priority queue's 40 starting positions are studied in descending order. Use this found record's “First position” field to find the starting position in symbol sequence array 10.

(b) Let b be the symbol in this first position. Let c be the symbol in next position (empty positions skipped). Let the symbol before b be “a” and the symbol after “c” be “d” thus forming a sequence abcd.

The left side. The variable LeftEqNum stores the number of replaceable occurrences changes for the pair bb and MiddleNum for the number for pair cb. The variable FirstPosAsymbol is set to the value of the symbol “a” in the sequence abcd if the pair ab's number of replaceable occurrences is decremented by 1.

FirstPosAsymbol =−1

If sgnA>0 Then

If sgnA=abs(c) Then

MiddleNum=MiddleNum +1

Elself sgnA <>abs(b) Then

FirstPosAsymbol=abs(a)

Else

If CountSimil(Left, position of “a”) Mod 2=0 Then

LeftEqNum=LeftEqNum+1

End If

End If

End If

The right side. The variable RightEqNum is for the number of replaceable occurrences for pair cc. The variable FirstPosDsymbol is set to the value of the symbol “d” in the sequence abcd if the pair cd's number is decremented by 1.

FirstPosDsymbol =−1

If sgnD>0 Then

If abs(d) =abs(b) Then

MiddleNum =MiddleNum +1

Elself abs(c) <>abs(d) Then

FirstPosDsymbol =abs(d)

Else

If CountSimil(Right, position of “d”) Mod 2 =0 Then

RightEqNum=RightEqNum+1

End If

End If

End If

Next, set the symbols b and c values negative indicating they are part of a first occurrence of a pair. Index the SymbolStart array by abs(b) and set this Symbolstart (abs(b)) to have a value of the position of b.

(c) Using the next pointer of this position in the symbol sequence array 10 study all the other occurrences of this pair bc.

If one of the symbols in an occurrence is negative then set the occurrence's first symbol's previous and next pointers to null (−1).

If in an occurrence both the first and second symbols are positive then find the number of consecutive occurrences of this pair requiring all symbols of these occurrences being positive. Let RLcount be this number (we use now abcbcbcd as an example, RLcount is thus 3). Comparing to Algorithm 1 the calls for the Decrement procedure are replaced with an addition operation.

wasmiddle =False

sgnA=symbol “a” with the sign i.e. sgnA can be also negative

If abs(b)<>abs(c) Then

FixPointers position of “a”, position of“d”, position of “a”, abs(a), abs(b)

If sgnA=abs(b) Then

If CountSimil(Left, position of “a”) Mod 2 =0 Then

LeftEqNum=LeftEqNum+1

End If

Elself sgnA =abs(c) Then

MiddleNum =MiddleNum+1

wasmiddle=True

End If

Elself abs(x)<>abs(b) Then

FixPointers position of “a”, position of “d”, position of “a”, abs(a), abs(b)

End If

Next the right pair cd is dealt with. The pair to be replaced is bc and “d” the symbol after the last pair. The variable wasmiddle is used ensure that the pair cb's pointers are set only once. Again, comparing to Algorithm 1 the procedure Decrement is replaced with addition operation.

sgnD=symbol “d” with the sign i.e. sgnD can be also negative

If abs(b)<>abs(c) Then

If abs(c) =abs(d) Then

FixPointers position of “a”, position of “d”, position of the last “c”, abs(c), abs (d)

If sgnD>0 Then

If CountSimil(Right, position of“d”) Mod 2 =0 Then

RightEqNum=RightEqNum +1

End If

End If

Elself abs(d)=abs(b) Then

If Not wasmiddle Then

FixPointers position of “a”, position of “d”, position of the last “c”, abs(c), abs(d)

wasmiddle=True

End If

If sgnD>0 Then

MiddleNum MiddleNum+1

End If

Else

FixPointers position of “a”, position of “d”, position of the last “c”, abs(c), abs (d)

End If

Elself abs(c)<>abs(d) Then

FixPointers position of “a”, position of “d”, position of the last “c”, abs(c), abs (d)

End If

Next, the middle pair cb. In a sequence abcbcbcd where RLcount is 3(3 occurrences of bc) there are 2 occurrences of cb. Again wasmiddle is used to ensure that the pointers of the middle pair are set only once.

If abs(b)<>abs(c) And RLcount>1 Then

If Not wasmiddle Then

FixPointers position of “a”, position of “d”, position of last “c”, abs(c), abs(b)

End If

MiddleNum =MiddleNum +RLcount - 1

End If

The special cases were thus handled. Now the general case.

The left side. The array LeftChanges is used to store the number of changes that occur for a pair and the position of first occurrence and position of last seen occurrence of the pair. The array LeftChangeInds stores all the indexes in LeftChanges that were modified. Index the array LeftChanges with abs(a). Consider the case that the field “Last seen previous position” is −1 indicating that LeftChanges at index abs(a) has not been modified. If the symbol “a” has a negative sing then set the field “number of changes” to be 0, otherwise set the “number of changes” to be 1. Also set the fields “First position” and “Last seen previous position” to the value of position of “a”. The symbol sequence array's 10 fields “Pointer to previous occurrence of this pair” and “Pointer to next occurrence of this pair” are set to null (−1). Now consider that LeftChanges indexed by abs(a) has a modified value. If symbol “a” has a positive sign then increment the field “number of changes” by 1. Also, update symbol sequence array's fields “Pointer to previous occurrence of this pair” and “Pointer to next occurrence of this pair” using the field “Last seen previous position” in the array LeftChanges. The field “Last seen previous position” in LeftChanges is then set to the value of position of “a”.

The right side. Now the array RightChanges is used to store the number of changes that occur for a pair and the position of first occurrence and position of last seen occurrence of the pair. The array RightChangeInds stores all the indexes in RightChanges that were modified. Index the array RightChanges with abs(d). Consider the case that the field “Last seen previous position” is −1 indicating that RightChanges at index abs(d) has not been modified. If symbol “d” has a negative sing then set the field “number of changes” to be 0, otherwise set the “number of changes” to be 1. Also, set the fields “First position” and “Last seen previous position” to the value of position of “d”. The symbol sequence array's 10 fields “Pointer to previous occurrence of this pair” and “Pointer to next occurrence of this pair” are set to null (−1). Now consider that RightChanges indexed by abs(d) has a modified value. If symbol “d” has a positive sign then increment the field “number of changes” by 1. Also, update symbol sequence array's fields “Pointer to previous occurrence of this pair” and “Pointer to next occurrence of this pair” using the field “Last seen previous position” in the array RightChanges. The field “Last seen previous position” in LeftChanges is then set to the value of position of “d”.

Next put the new symbol (let it now be E) RLcount times into positions starting from and including the now replaced sequence's first symbol “b”.

If RLcount is greater than 1 then there will be new occurrences of the pair EE. The array LeftChanges is used for this pair. The array LeftChangeInds stores all the indexes in LeftChanges that were modified. Now index array LeftChanges by E. Consider the case that the field “Last seen previous position” is −1 indicating that RightChanges at index E has not been modified. Set the “number of changes” to 0 and set a temporary variable Oldnum to 0 and set the fields “First position” and “Last seen previous position” to the value of the position of first E inserted in previous chapter. The symbol sequence array's fields “Pointer to previous occurrence of this pair” and “Pointer to next occurrence of this pair” are set to null (−1). Now consider that LeftChanges indexed by E has a modified value. Set the temporary variable Oldnum to the value of field “number of changes”. Update symbol sequence array's fields “Pointer to previous occurrence of this pair” and “Pointer to next occurrence of this pair” using the field “Last seen previous position” in the array LeftChanges. Consider now those E symbols inserted in previous chapter. In the symbol sequence array 10 set every E's but the two last one's next pointer to point to its own position plus 1 and the pointed E's previous pointer to its own position minus 1. The field “Last seen previous position” in LeftChanges at index E is set to the value of position of the last E minus 1. Also, the field “number of changes” is set to the value of Oldnum +RLcount2.

To skip the empty positions set the next pointer of the first and the previous pointer of the last of those positions that became empty because of replacement by 0.

This step 3(c) continues until all the occurrences of the pair have been studied.

(d) When all the occurrences of a pair have been studied for possible replacement, the first occurrence's first symbol's next pointer in the symbol sequence array 10 is set to null (−1). In addition, this pair's record is disconnected from its priority queue and hash table list, the record's previous and next records in the corresponding lists are connected to each other. Then the record is moved to the re-usable list 50 by setting the record's “Next in hash table list” pointer to point to the record pointed by Pairsfee variable and setting the Pairsfree to point to this record.

(e) Next, the 5 variables used for the special cases are dealt with. First the three variables LeftEqNum (pair bb), RightEqNum (pair cc) and MiddleNum (pair cb). Use hash table 20 to find the Pairs array record for each pair. Then decrement the number of replaceable occurrences in that record by the amount the variable tells and move the record to its proper place in priority queue 40 or into the list of reusable records 50. Next, the variables FirstPosAsymbol and FirstPosDsymbol that store the symbol values. Check if the array LeftChanges indexed by FirstPosAsymbol has a modified value. If this is not the case then find using the hash table the Pairs array record for pair “FirstPosAsymbol” “b” and decrement its number of replaceable occurrences by 1 and move the record to its proper place in the priority queue or into the list of re-usable records. Check if the array RightChanges indexed by FirstPosDsymbol has a modified value. If this is not the case then find using the hash table the Pairs array record for pair “c” “FirstPosDsymbol” and decrement its number of replaceable occurrences by 1 and move the record to its proper place in the priority queue or into the list of reusable records.

(f) The arrays LeftChanges and RightChanges store the needed information for those symbols that appeared at the left or the right side of the replaced pair. The arrays LeftChangeInds and RightChangeInds store the modified indexes of those arrays. Using the LeftChangeInds and RightChangeInds arrays all the modified indexes are studied. If in a modified index there is a nonzero number of replaceable occurrences change then find the Pairs array record for the decrementing pair in question using the hash table and decrement the number of replaceable occurrences by this value. (A modified index i in the array LeftChanges corresponds to a pair “LeftChanges(i)” “b” when bc is the pair whose occurrences were studied. A modified index i in the array RightChanges corresponds to a pair “c” “RightChanges(i)” when bc is the pair whose occurrences were studied.) Move the record into its proper place in the priority queue or into the list of re-usable records. The decrementing pairs for the special cases handled by LeftEqNum, MiddleNum and RightEqNum (pairs bb, cb and cc in a sequence bbcbcc when bc is replaced) are not handled—they are skipped since they were already handled as described in previous step (e). To know if a pair is one of the special cases the index of the arrays LeftChanges and RightChanges must be either b or c when bc is the pair to be replaced. When a decrementing pair is considered then if a modified index in the LeftChanges array equals to FirstPosAsymbol then the value of change is increased by 1. This incremented value is then decremented from the Pairs array record as described in this chapter. Similarly if a modified index in the RightChanges array equals to FirstPosDsymbol then the value of change is increased by 1. This incremented value is then decremented from the Pairs array record. Let E be the new symbol used to replace occurrences. A modified index i in the array LeftChanges corresponds now to a new pair “LeftChanges(i)” E. A modified index i in the array RightChanges corresponds to a new pair E“RightChanges(i)”. If the new number of replaceable occurrences is greater than Numlimit then those new pairs are hashed and inserted into the double linked hash table lists and into the priority queue lists. When an index in the arrays LeftChanges or RightChanges has been processed then the field “Last seen previous position” is set to −1 indicating that the index has not been modified.

The computation of this Step 3 will continue from the beginning of this step. The last steps 4, 5 and 6 are as in Algorithm A1.

Decompression, Algorithm B1 .

Recall that the compressed sequence consists of atomic symbols i.e. symbols from original uncompressed input and pointers. A pointer is a value of the position pointed to plus a value greater than any atomic symbol's value. This added value upperlimit is the first number greater than any atomic symbol.

For each position X in compressed input:

Step 1. Determine if a position X in compressed input contains an atomic symbol or a pointer: if the value is less than upperlimit then the position contains an atomic symbol.

Step 2. If a position X contains an atomic symbol then

copy the atomic symbol to the next unoccupied position Z in decompressed output and set

Length₁₃ of₁₃ position (X) 1

Starting₁₃ position(X)=Z

else if a position X contains a pointer to a position Y then set

E=Length₁₃ of₁₃ position(Y) +Length₁₃ of₁₃ position(Y+l)

and copy E positions to next unoccupied position Z in decompressed output from decompressed output from the position Starting₁₃ position(Y) and set

Length₁₃ of₁₃ position(X) =E

Starting₁₃ position(X) =Z.

The decompression is very straightforward and fast. Please notice that if the compressed sequence is Huffman compressed then immediately when the next symbol is discovered from Huffman code it can—if wanted—also be outputted to the decompression algorithm B1.

The memory requirements for this decompression algorithm B1 are 2 storage words for each position in compressed sequence. When a word occupies 4 bytes then 8 bytes per a position in compressed sequence is the memory needed. Recall that the algorithm Al compresses the first 1.000.000 bytes of the bible.txt in Canterbury corpus to 125.699 positions. The arrays used in decompression in this case thus require 1.005.592 bytes. If the compression algorithms presented are used to compress data that does not compress well then the number of positions in compressed sequence is larger. It is never however larger than the number of input symbols. If large amounts of data are to be compressed then the data is of course compressed in blocks. Determining the block size sets the upper limit for memory requirement.

Decompression, Algorithm B2.

If slighter slower decompression speed is tolerated then this algorithm can be used. Less memory is used. As in the algorithm B1 the arrays Length₁₃ of₁₃ position and Starting₁₃ position are used. Now they are not indexed by every position in compressed sequence—instead the length and the starting position information is stored only for those positions that are actually pointed to. Another array called IsPointedTo is indexed by every position; the value stored in this array is the index in arrays Length₁₃ of₁₃ position and Starting₁₃ position for those positions that are pointed to.

Step 1. Setj=−1

Step 2. Traverse the compressed positions once.

If a position has a pointer to position Y then

If IsPointedTo(Y) is empty then

j=j+1

IsPointedTo(Y)=j

End if

If IsPointedTo(Y+1) is empty then

j=j+1

IsPointedTo(Y+1)=j

End If

End if

Step 3. The compressed positions are traversed once and for each position X in compressed input:

(a) Determine if a position X in compressed input contains an atomic symbol or a pointer: if the value is less than upperlimit then the position contains an atomic symbol.

(b) If a position X contains an atomic symbol then:

copy the atomic symbol to the decompressed output to next unoccupied position Z

If IsPointedTo(X) is not empty then

W=IsPointedTo(X)

Length₁₃ of₁₃ position(W) =1

Starting₁₃ position(W)=Z

End if

else if a position X contains a pointer to a position Y then:

W1=IsPointedTo(Y)

W2=IsPointedTo(Y+1)

E=Length₁₃ of₁₃ position(W1)+Length₁₃ of₁₃ position(W2)

copy E positions to next unoccupied position Z in decompressed output from decompressed output from the position Starting_position(W1)

If IsPointedTo(X) is not empty then

W=IsPointedTo(X)

Length₁₃ of₁₃ position(W)=E

Starting₁₃ position(W)=Z

End If

End If

Considering the memory requirements it can be seen that the array IsPointedTo requires 1 word per position in compressed sequence. Every position that is pointed to adds two words to memory requirement.

1. ] a data compression method comprising the steps of:
(a) reading of input symbols, consider two adjacent symbols forming a pair, counting how many times each pair exists, a pair of two symbols is considered replaceable if both of its symbol positions are replaceable, in this step the number of replaceable occurrences is set to be the count how many times a pair exists
(b) inserting into a priority queue the records that contain the number of replaceable occurrences of pairs
(c) finding from the priority queue the pair having the greatest number of replaceable occurrences
(d) marking the symbol positions of the first occurrence of this pair in question not replaceable, if this marking causes a pair whose one symbol is the marked symbol to lose one replaceable occurrence then immediately changing the number in the pair's record and then immediately moving the pair's record into proper position in the priority queue
(e) studying the other occurrences of this pair and replacing each one of those occurrences whose both symbol positions are replaceable with one new symbol, wherein:
when a pair's number of replaceable occurrences is about to change then immediately changing the number in the record and then immediately moving the pair's record into proper position in the priority queue
(f) repeating the steps (c)-(e) until the greatest number of replaceable occurrences descents to a predetermined level
(g) if this predetermined level is 1 then traversing the symbol sequence once and if a pair has a second occurrence whose both symbols are positive then replacing this second occurrence with one new symbol
(h) transforming the new symbols into values indicating the position of the first symbol of the first occurrence of that pair the symbol was used to replace added by a constant value greater than any input symbol.

2. ] A method as in claim 1 wherein the step (d) and (e) are as follows:
(d) marking the symbol positions of the first occurrence of this pair in question not replaceable, if this marking causes a pair whose one symbol is the marked symbol to lose one replaceable occurrence then immediately changing the number in-the pair's record and then inserting the changed record's index or pointer to the record into an array or list if the index or pointer is not already there
(e) studying the other occurrences of this pair and replacing each one of those occurrences whose both symbol positions are replaceable with one new symbol, wherein:
when a pair's number of replaceable occurrences is about to change then immediately changing the number in the record and then inserting the changed record's index or pointer to the record into an array or list if the index or pointer is not already there, when all the occurrences of a pair have been studied then this array or list is traversed and the records are inserted into proper positions in the priority queue and the array or list is emptied.

3. ] A method as in claim 1 wherein the step (d) and (e) are as follows:
(d) marking the symbol positions of the first occurrence of this pair in question not replaceable, if this marking causes a pair whose one symbol is the marked symbol to lose one replaceable occurrence then updating the corresponding variable assigned for the case
(e) studying the other occurrences of this pair and replacing each one of those occurrences whose both symbol positions are replaceable with one new symbol, wherein
when a pair's number of replaceable occurrences is about to change then two arrays are used to store the number change, one for the left side changes caused by the disappearing occurrence and one for the right side changes,
these two array also store the needed information for new pairs i.e. the first occurrence's position and the last seen previous position, 5 variables are used to handle the special cases, three of them are for the cases when the number of replaceable occurrences increment differs from that of the decrement and two of them are for the both sides of the first occurrence of the pair,
when all the occurrences of a pair have been studied then these two arrays' modified positions are traversed, the number of replaceable occurrences changes are applied from the 5 variables and from the two arrays to records which are then moved into proper places in priority queue, the new pairs' records are created and the information is copied to them and they are inserted into proper positions in the priority queue.

4. ] A method of decompressing a compressed representation of a sequence of symbols, said compressed representation comprising of atomic symbols i.e. symbols from original uncompressed input and pointers to positions in compressed sequence, a pointer being a value of the position pointed to plus a value greater than any atomic symbol's value, said decompressing method comprising the steps of:
For each position X in compressed input:
(a) determining if a position X in compressed input contains an atomic symbol or a pointer
(b) if a position X contains an atomic symbol then copying the atomic symbol to next unoccupied position Z in decompressed output and setting Length₁₃ of₁₃ position (X)=1 and Starting₁₃ position(X)=Z else if a position X contains a pointer to a position Y then setting E=Length₁₃ of₁₃ position(Y)+Length₁₃ of₁₃ position(Y+1) and copying E positions to next unoccupied position Z in decompressed output from decompressed output from the position Starting₁₃ position(Y) and setting Length₁₃ of₁₃ position(X)=E and Starting₁₃ position(X)=Z.

5. ] A method of decompressing a compressed representation of a sequence of symbols, said compressed representation comprising of atomic symbols i.e. symbols from original uncompressed input and pointers to positions in compressed sequence, a pointer being a value of the position pointed to plus a value greater than any atomic symbol's value, said decompressing method comprising the steps of:
(a) traversing the compressed positions once and for each position Y pointed to
if IspointedTo(Y) is empty then
j=j+1
IsPointedTo(Y)=j
if IspointedTo( Y+1) is empty then
j=j+1
IsPointedTo(Y+1) =j
(b) traversing the compressed positions once and for each position X in compressed input:
(1) determining if a position X in compressed input contains an atomic symbol or a pointer
(2) If a position X contains an atomic symbol then copying the atomic symbol to the decompressed output to next unoccupied position Z
If IsPointedTo(X) is not empty then
W=IsPointedTo(X)
Length₁₃ of₁₃ position(W)=1
Starting₁₃ position(W)=Z else if a position X contains a pointer to a position Y then:
W1=IsPointedTo(Y)
W2=IsPointedTo(Y+1)
E=Length₁₃ of₁₃ position(W1) +Length₁₃ of₁₃ position(W2) copying E positions to next unoccupied position Z in decompressed output from decompressed output from the position Starting_position(W1) and setting
If IsPointedTo(X) is not empty then
W=IsPointedTo(X)
Length₁₃ of₁₃ position(W)=E
Starting₁₃ position(W) Z.
